(19) United States
(12) Patent Application Publication
(10) Pub. No.: US 2015/0303370 A1
(43) Pub. Date: Oct. 22, 2015

(54) PIEZOELECTRIC ACTUATOR AND APPARATUS FOR GENERATING VIBRATIONS INCLUDING THE SAME

(71) Applicant: SAMSUNG ELECTRO-MECHANICS CO., LTD., Suwon (KR)

(72) Inventors: Jae Kyung KIM, Suwon (KR); Joon CHOI, Suwon (KR); Yeon Ho SON, Suwon (KR)

(73) Assignee: SAMSUNG ELECTRO-MECHANICS CO., LTD., Suwon (KR)

(21) Appl. No.: 14/755,302

(22) Filed: Jun. 30, 2015

Related U.S. Application Data
(62) Division of application No. 13/766,022, filed on Feb. 13, 2013.

(30) Foreign Application Priority Data
Dec. 12, 2012 (KR) 10-2012-0144477

(51) Int. Cl. H01L 41/09; H01L 41/083

(52) U.S. Cl. CPC H01L 41/0933; H01L 41/083

(57) ABSTRACT

An apparatus for generating vibrations, the apparatus including in particular a piezoelectric actuator having positive electrode layers and negative electrode layers iteratively alternately vertically laminated; piezoelectric element layers interposed between the positive electrode layers and the negative electrode layers, respectively; a positive electrode connection pillar provided in a position corresponding to less than 50% of maximum displacement in the event of driving and penetrating the electrode layers and the piezoelectric element layers to connect the positive electrode layers; and a negative electrode connection pillar provided in a position corresponding to less than 50% of maximum displacement in the event of driving and penetrating the electrode layers and the piezoelectric element layers to connect the negative electrode layers.

### CROSS-REFERENCE TO RELATED APPLICATIONS

This application is a U.S. divisional application filed under 37 CFR 1.53(b) claiming priority benefit of U.S. Ser. No. 13/766,022 filed in the United States on Feb. 13, 2013, which claims earlier foreign priority benefit to Korean Patent Application No. 10-2012-0144477 filed with the Korean Intellectual Property Office on Dec. 12, 2012, the disclosures of which are incorporated herein by reference.

### BACKGROUND

1. Field

The present invention relates to a piezoelectric actuator and an apparatus for generating vibrations including the same.

2. Description of Related Art

An apparatus for generating vibrations, a component for converting electrical energy into mechanical vibrations by using a genetic principle of electromagnetic force, is installed in a portable phone so as to be used for silently notifying a user of receipt of an incoming call.

The rapid expansion of the phone market has promoted the addition of a variety of functions to portable phones. In line with this trend, components of portable phones have been required to be smaller and have high quality. In the case of an apparatus for generating vibrations, the development of a product having a novel structure that may improve shortcomings of existing products and having remarkably improved quality has been required.

As portable phones having large LCD screens have been increasingly launched onto the market in recent years, a touch screen scheme has been adopted and an apparatuses for generating vibrations have also been used to generate vibrations in the event of a touch.

An apparatus for generating vibrations used in portable phones employing a touch screen is more frequently used in the event of a touch than in the event of receipt of an incoming call, so it is required to have a longer operational lifespan and a fast response speed in line with a speed at which a user touches a touch screen.

To meet the requirements of lifespan and responsiveness, currently, portable phones employing a touch screen also employ a linear vibrator.

Rather than using a principle of a motor rotating an unbalanced weight, in a linear vibrator, a mass body hanging on a spring installed therein makes a linear resonant motion by electromagnetic force generated by a coil and a magnet to generate vibrations.

Alternatively, a piezoelectric element may be used as an actuator to enable a mass body to make a linear resonant motion, according to contraction and expansion of the piezoelectric element to generate vibrations.

The employment of a piezoelectric actuator using a piezoelectric element in an apparatus for generating vibrations is based on a principle that lengths of both sides of the piezoelectric actuator in a length direction based on a central portion of the piezoelectric actuator are changed.

However, in the related art, a portion connecting electrodes laminated upwardly and downwardly in the piezoelectric actuator is provided in an end portion of the piezoelectric actuator whose length is substantially changed, a recognized problem.

### SUMMARY

An aspect of the present invention provides a structure for easily connecting electrodes laminated vertically within a piezoelectric actuator.

Another aspect of the present invention provides a piezoelectric actuator in which vertically laminated electrodes are connected in a central portion which is not substantially changed.

According to an aspect of the present invention, there is provided a piezoelectric actuator including: positive electrode layers and negative electrode layers iteratively alternately vertically laminated; piezoelectric element layers interposed between the positive electrode layers and the negative electrode layers, respectively; a positive electrode (or anode) connection pillar provided in a position corresponding to less than 50% of maximum displacement in the event of driving (i.e., when the piezoelectric actuator is driven) and penetrating the electrode layers and the piezoelectric element layers to connect the positive electrode layers; and a negative electrode (or cathode) connection pillar provided in a position corresponding to less than 50% of maximum displacement in the event of driving and penetrating the electrode layers and the piezoelectric element layers to connect the negative electrode layers.

The positive electrode layers may have a quadrangular shape having a horizontal side and a vertical side, and the positive electrode connection pillar and the negative electrode connection pillar may be provided in a position corresponding to less than 50% of maximum displacement in the event of driving in a horizontal direction.

The positive electrode layer may have a positive dummy pattern formed on one side of a portion corresponding to less than 50% of maximum displacement in a vertical direction in the event of driving in a horizontal direction, and separated from the positive electrode layer, the negative electrode layer may have a negative dummy pattern formed in the other side of the portion corresponding to less than 50% of maximum displacement in a vertical direction in the event of driving in the horizontal direction, and separated from the negative electrode layer, the positive electrode may be connected in a penetrative manner vertically in the other side in a vertical direction where the negative dummy pattern is provided, and the negative electrode connection pillar may be connected in a penetrative manner vertically on one side in the vertical direction where the positive electrode dummy pattern is provided.

The positive electrode dummy pattern and the negative electrode dummy pattern may be provided symmetrically, based on the center of the piezoelectric actuator in the vertical direction and have the same shape.

The vertical side may be shorter than the horizontal side

The lowermost layer of the electrode layers may not have a dummy pattern.

Only a connection pillar having a corresponding polarity may be connected to the lowermost layer of the electrode layers.

An external electrode exposed to the outside so as to be electrically connected to the positive electrode layer and the negative electrode layer may be provided in a position corresponding to less than 50% of maximum displacement in the event of driving.

According to another aspect of the present invention, there is provided an apparatus for generating vibrations, including: a housing having an internal space; a direction changing member installed in the housing so as to be disposed in the internal space; a piezoelectric actuator fixed to the direction changing member such that a horizontal deformation thereof is formed, and deforming the direction changing member by a horizontal deformation thereof; and a vibrator fixed to the direction changing member and vertically displaced in a vertical direction according to a vertical deformation of the piezoelectric actuator.

The direction changing member may include: a fixed end fixed to the housing; horizontal portions extending from the fixed end to both sides in a horizontal direction; vertical portions extending from horizontal outer portions of the horizontal portions downwardly in a vertical direction; and displacement extending portions extending from vertical lower portions of the vertical portions to both sides in a horizontal direction and having the vibrator fixed to both sides thereof in the horizontal direction.

The piezoelectric actuator may be provided in a space formed by the horizontal portions and the vertical portions.

The piezoelectric actuator may be attached to one surface of at least any one of an upper surface in a vertical direction and end and side surfaces in a horizontal direction.

The housing may include a bracket on which the direction changing member is installed; and a case covering the bracket and incorporated with the bracket to provide an internal space.

The apparatus may further include a board attached to the bracket and providing power to the piezoelectric actuator.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view of an apparatus for generating vibrations according to an embodiment of the present invention;

FIGS. 2A through 2C are cross-sectional views of the apparatus for generating vibrations of FIG. 1 taken along line a portion A-A′;

FIG. 3 is a coupled perspective view of the apparatus for generating vibrations according to an embodiment of the present invention;

FIG. 4 is an exploded perspective view of the apparatus for generating vibrations according to an embodiment of the present invention;

FIGS. 5A and 5B are views illustrating an operation of the apparatus for generating vibrations according to an embodiment of the present invention;

FIG. 6 is an exploded perspective view of a piezoelectric actuator according to an embodiment of the present invention; and

FIG. 7 is an exploded perspective view of a piezoelectric actuator according to another embodiment of the present invention.

### DESCRIPTION OF EMBODIMENTS

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

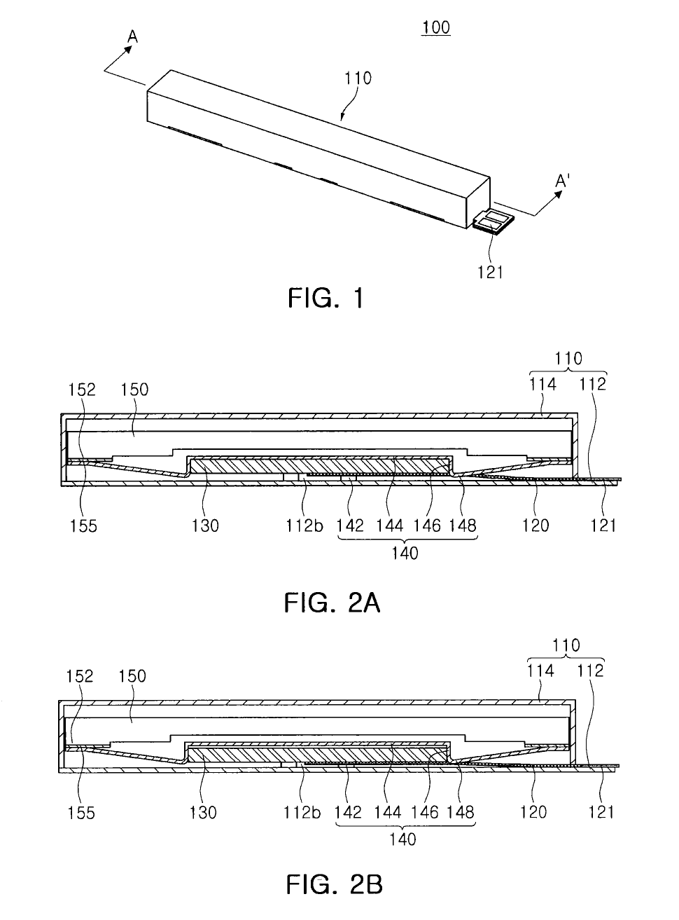

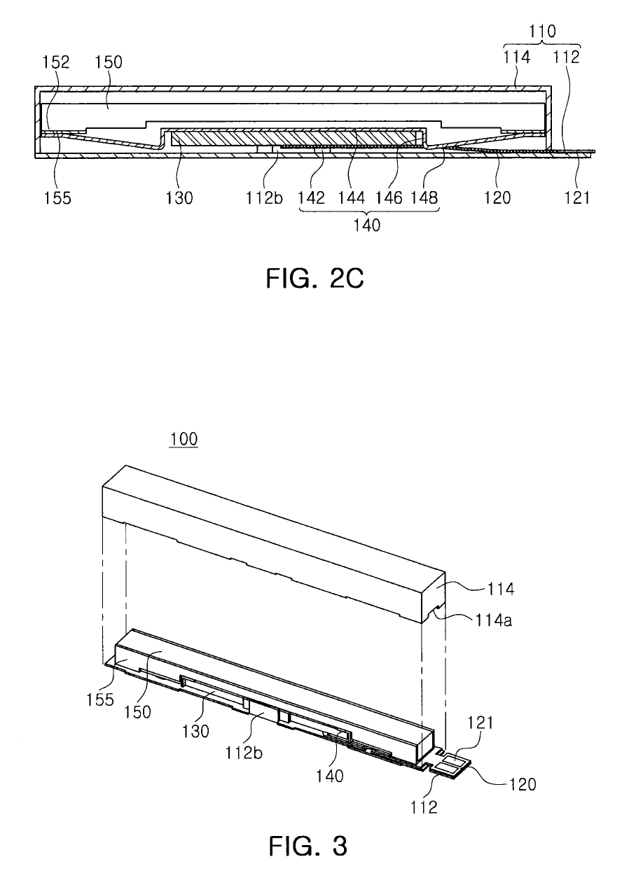

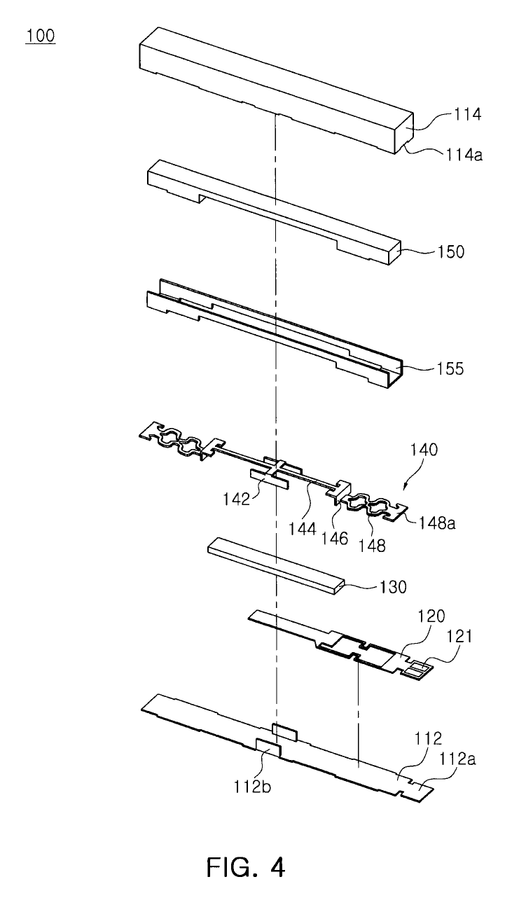

FIG. 1 is a perspective view of an apparatus for generating vibrations according to an embodiment of the present invention. FIGS. 2A through 2C are cross-sectional view of the apparatus for generating vibrations of FIG. 1 taken along line a portion A-A′. FIG. 3 is a coupled perspective view of the apparatus for generating vibrations according to an embodiment of the present invention. FIG. 4 is an exploded perspective view of the apparatus for generating vibrations according to an embodiment of the present invention.

Referring to FIGS. 1 through 4, an apparatus for generating vibrations 100 according to an embodiment of the present invention may include a housing 110 forming the exterior of the apparatus for generating vibrations 100, a board 120 providing power, piezoelectric actuator 130 contracting and expanding in a horizontal direction according to a power supplied thereto, a direction changing member 140 fixed in the housing 110 and having the piezoelectric actuator 130 mounted thereon, and a vibrator (or a weight) 150 fixed to the direction changing member 140, a vertical displacement of the vibrator 150 being changed according to a horizontal deformation of the piezoelectric actuator 130.

First, directional terms are defined as follows. In FIGS. 2A, 2B, and 2C, a horizontal direction may refer to a left-right direction, namely, a direction (i.e., a length direction) from one end of the piezoelectric actuator 130 or the vibrator 150 toward the other end thereof, and a vertical direction may refer to an upward or a downward direction, namely, a direction (i.e., a height direction) from the bottom of the piezoelectric actuator 30 or the vibrator 150 toward the top thereof. However, the horizontal direction may not refer to a particular direction but include any direction as long as it is on a horizontal plane, and the vertical direction may include any direction as long as it is perpendicular to the horizontal direction.

Meanwhile, with respect to a member of which any one of width and length thereof is longer, a width direction may refer to a direction having a shorter length. For example, in case that the width is longer than the length, a vertical direction may be a width direction. Here, the width direction may be a horizontal direction (i.e., a length direction) as described above

Also, a main surface may be the largest surface of a predetermined member, e.g., the piezoelectric actuator 130 or the vibrator 150.

Also, an outer side of the predetermined member may refer to a leftward-rightward direction in a horizontal direction substantially based on the center of the vibrator 150, and conversely, an inner side of the predetermined member may refer to a substantially central direction of the vibrator 150 in the leftward-rightward direction in the horizontal direction.

The housing 110 has an inner space and forms the exterior of the apparatus 100 for generating vibrations. The housing 110 may include a bracket 112 and a case 114. A direction changing member 140 may be installed on the bracket 112. Also, the board 120 may be installed on the bracket 112.

Also, the case 114 may cover the bracket 112 and may be incorporated with the bracket 112 to provide an internal space.

Here, in an embodiment of the present invention, the board 120 or the direction changing member 140 are installed on the bracket 112, but the present invention is not limited thereto and the board 120 or the direction changing member 140 may be installed on the case 114.

The bracket 112 may have a plate-like shape to allow a member to be easily installed thereon. Also, the case 114 may have a box-like shape with an opened lower surface, i.e., a hexahedral shape, to cover the entirety of the bracket 112.

Of course, the shape of the bracket 112 or the case 114 is not limited thereto and may have various other shapes. For example, the bracket 112 may be provided as a circular plate and the case may have a cylindrical shape covering the circular plate to provide an internal space.

The board 120 may be fixedly installed on the bracket 112. The board 120 may be installed on an inner surface of the housing 110 so as to be positioned in the internal space of the housing 110 or may be installed on an outer surface of the housing 110. The board 120 may be a printed circuit board, specifically, a flexible PCB (FPCB). Hereinafter, a case in which the substrate 120 is installed on an inner surface of the housing 110 will be described as an embodiment.

Also, in the case that the board 120 is installed on an inner surface of the housing 110, the board 120 may include a terminal connection portion 121 exposed to the outside of the housing 110.

The housing 110 may have a through hole 114a allowing the terminal connection portion 121 to be exposed therethrough. In particular, the through hole 114a may be provided in an end portion of the case 114 in a horizontal direction. In addition, the bracket 112 includes a terminal support portion 112a provided in a position corresponding to the position of the through hole 114a and outwardly protruded, and the terminal connection portion 121 may extend to an upper surface of the terminal support portion 112a.

Meanwhile, the board 120 may be fixedly installed on an upper surface of the bracket 112. In an embodiment of the present invention, the vibrator vibrates in the internal space, so the board 120 may be fixed to the bracket 112 such that it is not in contact with the vibrator, and extend to a portion where the piezoelectric actuator 130 is positioned, so as to be connected to the piezoelectric actuator 130.

Also, the bracket 112 may include a connection portion 112b to which the direction changing member 140 is fixedly installed. In detail, a fixed end 142 (to be described hereinafter) of the direction changing member 140 may be coupled to the connection portion 112b. The connection portion 112b may be substantially provided in the center of the bracket 112 and may have a plate-like shape protruded upwardly in a vertical direction at both sides of the bracket 112 in a width direction. Of course, the fixed end 142 may have a shape corresponding thereto. The connection portion 112b and the fixed end 142 may be connected through a coupling means such as welding, by applying an adhesive, or the like.

The direction changing member 140 may be installed to be positioned in the internal space of the housing 110. The direction changing member 140 may have the vibrator 150 (or a weight) (to be described hereinafter) installed on an upper portion thereof. The direction changing member 140 may cause a vertical displacement of the vibrator 150 installed on an upper portion thereof according to a horizontal deformation (i.e., expansion or contraction) of the piezoelectric actuator 130 installed therein.

The direction changing member 140 according to an embodiment of the present invention may include an elastic member extending outwardly in the horizontal direction based on the center of the apparatus 100 for generating vibrations, and in this case, the elastic member is deformed in a vertical direction according to a horizontal deformation of a piezoelectric element installed on the elastic member.

In detail, the direction changing member 140 according to one embodiment of the present invention may include the fixed end 142 fixed to the housing 110, at least two horizontal portions 144 extending from the fixed end 142 in a horizontal direction, vertical portions 146 extending from horizontal outer portions of the horizontal portions 144 downwardly in a vertical direction, and displacement extending portions 148 extending from vertical lower portions of the vertical portions 146 to both sides in a horizontal direction and having the vibrator 150 fixed to both sides thereof in the horizontal direction.

Here, the piezoelectric element provided in the piezoelectric actuator 130 may be provided in a space formed by the horizontal portion 144 and the vertical portion 146.

In the present embodiment, two or more horizontal portions 144 may be provided, and thus, two or more vertical portions 146 and displacement extending portions 148 may extend from the horizontal portions 144 in a corresponding manner.

Hereinafter, for the purposes of description, the case in which two horizontal portions 144 are provided will be described with reference to the accompanying drawings.

The direction changing member 140 according to the present embodiment may include the fixed end 142 fixed to the housing 110, the horizontal portions 144 extending from the fixed end 142 to both sides in the horizontal direction, the vertical portions 146 extending from horizontal outer portions of the horizontal portions 144 downwardly in a vertical direction, and the displacement extending portions 148 extending from vertical lower portions of the vertical portions 146 to both sides in a horizontal direction and having the vibrator 150 fixed to both sides thereof in the horizontal direction.

The fixed end 142 may be fixedly installed in the connection portion 112b provided in the bracket 112. The fixed end 142 may have a shape corresponding to the connection portion 112b.

The horizontal portions 144 may extend from the fixed end 142 to both sides in the horizontal direction. The horizontal portions 144 may be warped. The horizontal portions 144 may be substantially parallel to the horizontal direction.

Next, the vertical portions 146 may extend from horizontal outer portions of the horizontal portions 144 downwardly in a vertical direction. The horizontal portions 144 may be combined to the vertical portions 146 at a right angle.

The piezoelectric actuator 130 may be provided in a space formed by the horizontal portions 144 and the vertical portions 146. Namely, the piezoelectric actuator 130 may be fixed in the space formed by the horizontal portions 144 and the vertical portions 146 such that a horizontal deformation thereof is restrained, to deform the direction changing member 140 (i.e., to change a shape of the direction changing member 140) by horizontal deformation thereof. Thus, a vertical upper portion of the piezoelectric actuator 130 may be attached to the horizontal portions 144 (please see FIG. 2B). Also, both horizontal ends of the piezoelectric actuator 130 may be attached to the vertical portions 146 (please see FIG. 2C). Alternatively, vertical upper portions and both horizontal ends of the piezoelectric actuator 130 may be attached to the horizontal portions 144 and the vertical portions 146 (please see FIG. 2A).

Meanwhile, the displacement extending portions 148 may extend from the vertical lower portions of the vertical portions 146 to outer sides in the horizontal direction and having the vibrator 150 fixed to horizontal outer portions thereof. Namely, the displacement extending portions 148 may extend from the vertical lower portions of the vertical portion 146 to outer sides in a horizontal direction to expand a vertical displacement of the vibrator 150. Namely, the vertical portions 146 are coupled to the horizontal portions 144 and the horizontal portions 144 are warped in a vertical direction. Thus, the portions maximally outwardly extending from the vertical portions 146 in the horizontal direction may be maximally warped in the vertical direction.

Here, in order to maximize space utilization of the small apparatus 100 for generating vibrations according to the present embodiment, the portions of the displacement extending portions 148 coupled to the vertical portions 144 may be lower in the vertical direction than portions fixed to the vibrator 150. Namely, the displacement extending portions 148 may be sloped upwardly in the vertical direction from the portions thereof coupled to the vertical portions 144 toward outer sides in the horizontal direction.

Also, the vibrator 150 may be fixed to horizontal outer portions of the displacement extending portions 148. The displacement extending portions 148 may include coupling portions 148a formed on horizontal outer portions, to which the vibrator 150 is fixed, such that it is parallel to the horizontal direction.

Hereinafter, a warping mechanism of the horizontal portions 144 based on the structure in which the piezoelectric actuator is coupled to the horizontal portions 144 and the vertical portions 146 will be described.

In the case that the vertical upper portion of the piezoelectric actuator is attached to the horizontal portions 144 (please see FIG. 2B), when the piezoelectric actuator is deformed lengthwardly in a horizontal direction, the horizontal portions 144 to which the piezoelectric actuator 130 is restrained may be warped. Namely, when the length of the piezoelectric actuator is deformed in a horizontal direction, the horizontal portions 144, whose length is not deformed, are warped. In this case, the horizontal portions 144 may be warped such that both ends, based on the center of the piezoelectric actuator, are bent upwardly or downwardly in a vertical direction. In other words, when the length of the piezoelectric actuator elongates in a horizontal direction, both ends of the horizontal portions 144 may be bent upwardly in a vertical direction. Also, when the length of the piezoelectric actuator is reduced in a horizontal direction, both ends of the horizontal portions 144 may be bent downwardly in a vertical direction.

In case that both horizontal ends of the piezoelectric actuator are attached to the vertical portions 146 (in the case of FIG. 2C), when the length of the piezoelectric actuator is changed in a horizontal direction, the vertical portions 146 to which the piezoelectric actuator is restrained is pushed or pulled to both sides in a horizontal direction based on the center of the piezoelectric actuator. In this case, since the vertical portions 146 extend downwardly from outer ends of the horizontal portions 144 in a vertical direction. Torque is generated based on the portions in which the horizontal portions 144 and the vertical portions 146 meet, causing the horizontal portions 144 to be warped. In this case, the horizontal portions 144 are warped such that both ends thereof, based on the center of the piezoelectric actuator, are bent upwardly or downwardly in a horizontal direction. In other words, when the length of the piezoelectric actuator elongates in a horizontal direction, the vertical portions 146 are pushed outwardly, so the both ends of the horizontal portions 144 may be bent upwardly in a vertical direction. Also, when the length of the piezoelectric actuator is reduced in a horizontal direction, the vertical portions 146 are pulled inwardly, so both ends of the horizontal portions 144 may be bent downwardly in a vertical direction.

In the case that the vertical upper portions and the both horizontal ends of the piezoelectric actuator are attached to the horizontal portions 144 and the vertical portions 146 (i.e., in the case of FIG. 2A), the two foregoing cases may take place in a complex manner. Namely, warping of the horizontal portions 144 due to a difference between horizontal deformations of the horizontal portions 144 and the piezoelectric actuator and warping of the horizontal portions 144 due to a displacement of the vertical portions 146 in both sides may occur concurrently. In this case, a vertical deformation of the direction changing member 140 may be more effective.

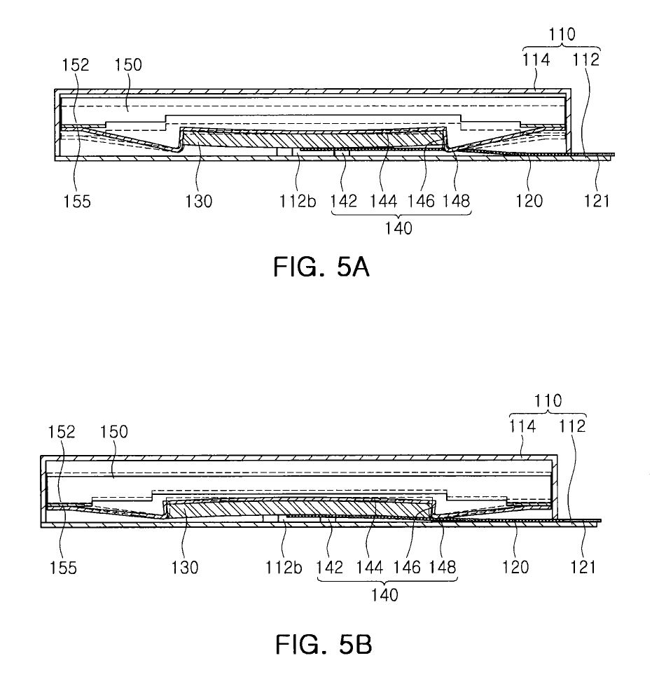

In detail, FIG. 5A illustrates a configuration in which the piezoelectric actuator 130 expands in a horizontal direction, and FIG. 5B illustrates a configuration in which the piezoelectric actuator 130 contracts in a horizontal direction.

Referring to FIG. 5A, as the piezoelectric actuator 130 expands in a horizontal direction, the horizontal outer ends of the horizontal portions 144 are warped upwardly in a vertical direction. Thus, horizontal outer portions of the displacement extending portion 148 extending from the horizontal portions 144 in a horizontal direction by the medium of the vertical portions 146 are lifted upwardly in a vertical direction. Accordingly, the vibrator 150 coupled to the horizontal outer portions of the displacement extending portions 148 is displaced upwardly in a vertical direction.

Referring to FIG. 5B, as the piezoelectric actuator 130 contracts in a horizontal direction, the horizontal outer ends of the horizontal portions 144 are warped downwardly in a vertical direction. Accordingly, the horizontal outer portions of the displacement extending portion 148 extending from the horizontal portions 144 by the medium of the vertical portions 146 in a horizontal direction are flowered downwardly in a vertical direction. Accordingly, the vibrator 150 coupled to the horizontal outer portions of the displacement extending portions 148 is displaced downwardly in a vertical direction.

As illustrated in FIGS. 5A and 5B, as the piezoelectric actuator 130 expands and contracts iteratively in a horizontal direction, the vibrator 150 installed on an upper end of the direction changing member 140 vibrates downwardly or upwardly in a vertical direction.

Meanwhile, the piezoelectric actuator 130 installed in the space formed by the horizontal portions 144 and the vertical portions 146 expand and contract iteratively in a horizontal direction. In this case, the horizontal center of the piezoelectric actuator 130 is maintained in the same position, rather than moving in a horizontal direction. Namely, only the horizontal center of the respective portions of the piezoelectric actuator 130 is maintained in a fixed state without being displaced in any direction. Thus, in the case of the piezoelectric actuator 130 installed in the apparatus 100 for generating vibrations according to an embodiment of the present invention, a structure connecting electrodes provided in the piezoelectric actuator 130 may be provided in a position corresponding to less than 50% of maximum displacement in the event of driving in a horizontal direction. As illustrated, in the case that the direction changing member 140 corresponding to a substantially central portion of the piezoelectric actuator 130 is fixed to the bracket 114, an electrode connection structure may be provided in a position corresponding to less than 50% of maximum displacement in the event of driving from the substantially horizontal central portion to both sides in a horizontal direction. However, the present invention is not limited thereto and, for example, in case that the direction changing member 140 corresponding to both horizontal end portions of the piezoelectric actuator 130 is fixed to the bracket 112, the electrode connection structure may be provided in a position corresponding to less than 50% of maximum displacement in the event of driving from the both horizontal end portions to the inner side in a horizontal direction.

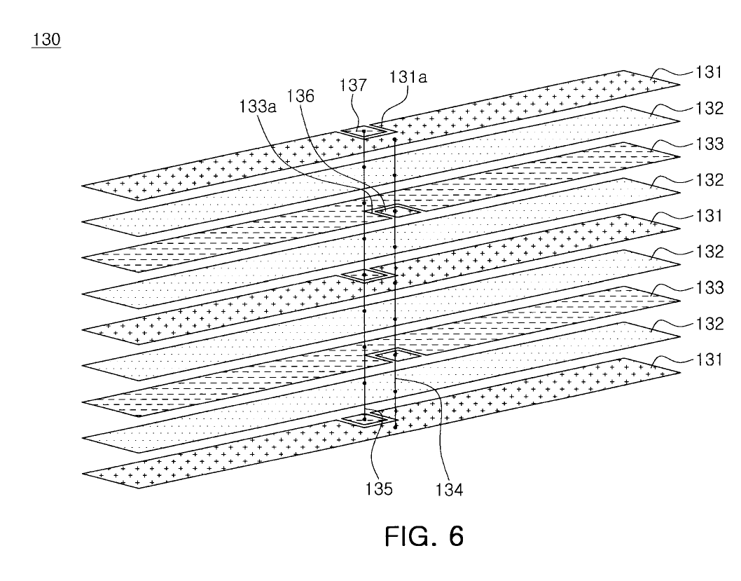

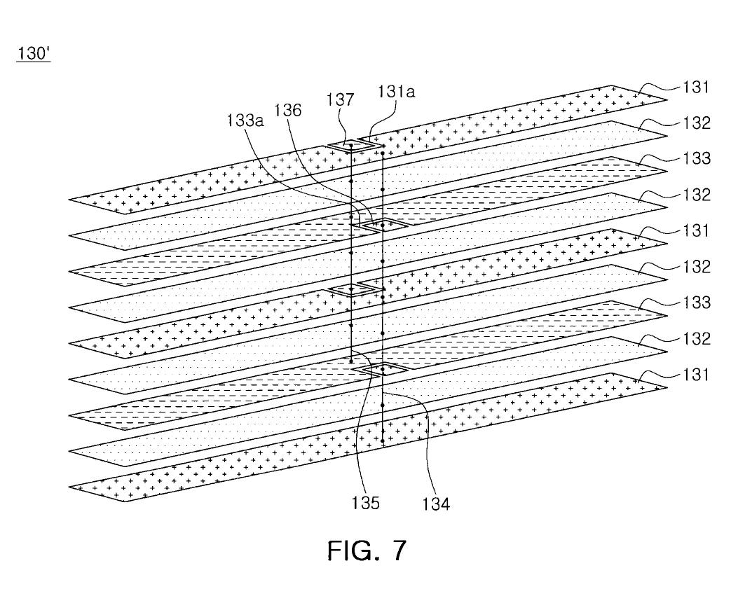

In this manner, when the electrode connection structure is provided in the portion corresponding to less than 50% of maximum displacement in the event of driving, the piezoelectric actuator 130 of the portion in which the electrode connection structure is provided corresponds to a portion which is relatively less deformed. Thus, reliability of the electrode connection structure can be enhanced. This will be described in detail with reference to FIGS. 6 and 7.

The piezoelectric actuator 130 may be installed in the direction changing member 140. In detail, the piezoelectric actuator 130 may be disposed in a space formed by the vertical portions 144 and the horizontal portions 146. In an embodiment of the present invention, the piezoelectric actuator 130 may have a structure in which electrodes and piezoelectric elements are laminated iteratively. When power is applied to the electrodes, the piezoelectric elements may expand and contract iteratively in a horizontal direction. Power may be provided from the board 120 connected to an external power line. The piezoelectric actuator 130 may be installed extendedly in a horizontal direction.

Also, the piezoelectric actuator 130 may be fixed in the space formed by the horizontal portions 144 and the vertical portions 146 such that a horizontal deformation thereof is restrained, to deform the direction changing member 140 (i.e., change a shape of the direction changing member 140) by a horizontal deformation thereof. Thus, a vertical upper portion of the piezoelectric actuator 130 may be attached to the horizontal portions 144 (please see FIG. 2B). Also, both horizontal ends of the piezoelectric actuator 130 may be attached to the vertical portions 146 (please see FIG. 2C). Alternatively, vertical upper portions and both horizontal ends of the piezoelectric actuator 130 may be attached to the horizontal portions 144 and the vertical portions 146 (please see FIG. 2A).

The vibrator 150 may be disposed on an upper portion of the direction changing member 140, specifically, on an upper portion of the coupling portion 148a as an outer end of the displacement extending portion 148. The vibrator 150 may be a weight made of a high specific gravity material. The vibrator 150 may be made of a copper-based material such as brass, or the like, or a tungsten material.

The vibrator 150 may be disposed extendedly in a horizontal direction. Namely, the vibrator 150 may be disposed extendedly relative to the piezoelectric actuator 130 and have a portion protruded to outer sides of the outer end of the piezoelectric actuator 130.

The vibrator 150 may have a weight adding portion 152 extending downwardly in a vertical direction at an outer side of the outer end of the piezoelectric actuator 130. The weight adding portion 152 may be integrally provided with the vibrator 150 or may be separately provided and attached.

The displacement extending portion 148 may be provided such that the coupling portion 148a thereof, an outer portion thereof in a horizontal direction, is distant by as much as possible from the center of the piezoelectric actuator 130, in order to maximize a vertical displacement of the apparatus 100 for generating vibrations. The protruded portion maximally protruded from the vibrator 150 in a horizontal direction may be coupled to the coupling portion 148a. In detail, the portion in which the weight adding portion 152 is provided may be coupled to the coupling portion 148a.

Meanwhile, a holder 155 may be interposed between the vibrator 150 and the direction changing member 140, specifically, the coupling portion 148a as an outer end of the displacement extending portion 148. The holder 155 may have a shape covering the vibrator 150.

FIG. 6 is an exploded perspective view of a piezoelectric actuator according to an embodiment of the present invention. FIG. 7 is an exploded perspective view of a piezoelectric actuator according to another embodiment of the present invention.

Referring to FIG. 6, the piezoelectric actuator 130 according to an embodiment of the present invention is disclosed.

The piezoelectric actuator 130 according to an embodiment of the present invention may include positive electrode layers 31 and negative electrode layers 32 iteratively alternately vertically laminated; piezoelectric element layers 132 interposed between the positive electrode layers 131 and the negative electrode layers 133, respectively; a positive electrode (or anode) connection pillar 134 provided in a position corresponding to less than 50% of maximum displacement in the event of driving and penetrating the electrode layers and the piezoelectric element layers 132 to connect the positive electrode layers 131; and a negative electrode (or cathode) connection pillar 135 provided in a position corresponding to less than 50% of maximum displacement in the event of driving and penetrating the electrode layers and the piezoelectric element layers 132 to connect the negative electrode layers 133. In FIG. 6, it is illustrated that the positive electrode connection pillar 134 and the negative electrode connection pillar 135 are provided in a substantially central portion of the piezoelectric actuator 130, but the present invention is not limited thereto and the positive electrode connection pillar 134 and the negative electrode connection pillar 135 may be provided in an end portion of the piezoelectric actuator 130, a portion inclined to one side from the center of the piezoelectric actuator 130, or the like, as long as such a portion corresponds to less than 50% of maximum displacement in the event of driving.

In FIG. 6, it is illustrated that the positive electrode connection pillar 134 and the negative electrode connection pillar 135 connect both the uppermost layer and the lowermost layer in the exploded perspective view, but this is only for the purpose of illustrating the interlayer connection structure and actual lengths of the positive electrode connection pillar 134 and the negative electrode connection pillar 135 are not substantially the same as those illustrated. The actual lengths of the positive electrode connection pillar 134 and the negative electrode connection pillar 135 may be equal to a thickness in a state that all the layers including the uppermost layer and the lowermost layer are attached, i.e., vertical lengths.

Namely, the piezoelectric actuator 130 may be formed by laminating the positive electrode 131, the piezoelectric element layer 132, and the negative electrode layer 133 iteratively in a vertical direction, namely, up and down. Thus, the positive electrode 131, the piezoelectric element layer 132, and the negative electrode layer 133 may be provided to have the same size.

Here, the positive electrode 131, the negative electrode layer 133, and the piezoelectric element layer 132 may have a quadrangular shape having a horizontal side and a vertical side, and the positive electrode connection pillar 134 and the negative electrode connection pillar 135 may be provided in a position corresponding to less than 50% of maximum displacement in the event of driving in a horizontal direction. Of course, the shape of the positive electrode 131, the negative electrode layer 133, and the piezoelectric element layer 132 is not limited to the quadrangular shape, and the positive electrode 131, the negative electrode layer 133, and the piezoelectric element layer 132 may have a circular shape, or any other polygonal shapes than a quadrangular shape. Meanwhile, a vertical side of the piezoelectric actuator 130 applied to the apparatus 100 for generating vibrations according to an embodiment of the present invention may be shorter than a horizontal side thereof. Namely, the piezoelectric actuator 130 may have a quadrangular shape, elongated in one direction.

The positive electrode layer 131, the negative electrode layer 133, the positive electrode connection pillar 134, and the negative electrode connection pillar 135 may be made of a conductive metal. Of course, the material of the positive electrode layer 131, the negative electrode layer 133, the positive electrode connection pillar 134, and the negative electrode connection pillar 135 is not limited thereto and any material may be easily utilized as long as it is conductive. The piezoelectric element layer 132 may be made of a piezoelectric material, preferably, a lead zirconate titanate (PZT) ceramic material.

The positive electrode layer 131 may include a positive electrode dummy pattern 136 formed on one side of a portion corresponding to less than 50% of maximum displacement in a vertical direction in the event of driving in a horizontal direction and separated from the positive electrode layer 131. The negative electrode layer 133 may have a negative electrode dummy pattern 137 formed in the other side of the portion corresponding to less than 50% of maximum displacement in the vertical direction in the event of driving in a horizontal direction and separated from the negative electrode layer 133. Namely, the positive electrode layer 131 and the negative electrode layer 133 may have the positive electrode dummy pattern 135 and the negative dummy pattern 137 electrically separated in each layer, respectively.

The negative electrode connection pillar 135 may be provided in a vertical direction to connect the negative electrode layers 133. Namely, the negative electrode connection pillar 135 may connect the negative electrode 133 and the positive dummy pattern 136, provided on the same layer as the positive electrode layer 131 but electrically separated therefrom. Due to the presence of the positive dummy pattern 136, although the negative electrode connection pillar 135 passes through the same layer as the positive electrode layer 131, it may not be electrically connected to the positive electrode layer 131. Thus, the negative electrode connection pillar 135 may be connected in a penetrative manner vertically on one side in a vertical direction where the positive electrode dummy pattern 136 is provided.

Meanwhile, although not shown, the positive electrode dummy patterns 136 may be provided in different positions of the respective positive electrode layers 131 iteratively laminated. Namely, the positive electrode dummy patterns 136 provided on different layers may be provided in different positions in a horizontal direction as long as the portions correspond to less than 50% of maximum displacement in the positive electrode layers 131 in the event of driving in a horizontal direction. In this case, the negative electrode connection pillar 135 may not be provided to penetrate the piezoelectric actuator 130 on the whole in a straight line in a vertical direction and two or more negative electrode connection pillars 135 may be provided in different positions in a horizontal direction according to positions of the positive electrode dummy patterns 136. Of course, the two or more negative electrode connection pillars 135 may be electrically connected in a predetermined negative electrode layer 135 within the piezoelectric actuator 130.

The positive electrode connection pillar 134 may be provided in a vertical direction to connect the positive electrode layers 131. Namely, the positive electrode connection pillar 134 may connect the positive electrode layer 131 and the negative dummy pattern 137, provided on the same layer as the negative electrode layer 133 but electrically separated therefrom. Due to the presence of the negative dummy pattern 137, although the positive electrode connection pillar 134 passes through the same layer as the negative electrode layer 133, it may not be electrically connected to the negative electrode layer 133. Thus, the positive electrode connection pillar 134 may be connected in a penetrative manner up and down in the other side in a vertical direction where the negative electrode dummy pattern 137 is provided.

Meanwhile, although not shown, the negative electrode dummy patterns 137 may be provided in different positions of the respective negative electrode layers 133 iteratively laminated. Namely, the negative electrode dummy patterns 137 provided on different layers may be provided in different positions in a horizontal direction as long as the portions correspond to less than 50% of maximum displacement in the negative electrode layers 133 in the event of driving in a horizontal direction. In this case, the positive electrode connection pillar 134 may not be provided to penetrate the piezoelectric actuator 130 on the whole in a straight line in a vertical direction, and two or more positive electrode connection pillars 134 may be provided in different positions in a horizontal direction according to positions of the negative electrode dummy patterns 137. Of course, the two or more positive electrode connection pillars 134 may be electrically connected in a predetermined positive electrode layer 131 within the piezoelectric actuator 130.

Meanwhile, the positive electrode dummy pattern 136 and the negative electrode dummy pattern 137 may be positioned to be symmetrical based on the center of the piezoelectric actuator 130 in a vertical direction and have the same shape. For example, as illustrated in FIG. 6, the positive electrode dummy pattern 136 and the negative electrode dummy pattern 137 may have a quadrangular shape. Of course, the present invention is not limited thereto and the positive electrode dummy pattern 136 and the negative electrode dummy pattern 137 may have a polygonal shape other than a rectangular shape, or a rounded shape, in particular, a semicircular shape. The positive electrode dummy pattern 136 and the negative electrode dummy pattern 137 may be disposed in a crisscross manner in a horizontal direction. Namely, the positive electrode dummy pattern 136 and the negative electrode dummy pattern 137 may be disposed in a crisscross manner in a horizontal direction in a portion as long as the portion corresponds to less than 50% of maximum displacement in the event of driving. Also, the positive electrode dummy pattern 136 and the negative electrode dummy pattern 137 may not necessarily have the same shape.

In the case in which the positive electrode dummy pattern 136 and the negative electrode dummy pattern 137 have a quadrangular shape as illustrated in FIG. 6, the positive electrode layer 131 and the negative electrode layer 133 may have a positive electrode dummy pattern formation portion 133a and a negative dummy pattern formation portion 131a having a size greater than that of the rectangular positive electrode dummy pattern 136 and the negative electrode. Namely, portions in which the positive electrode layer 131 and the negative electrode layer 133 are omitted may be formed substantially in the center of the same layer as the positive electrode layer 131 and the negative electrode layer 133 in a horizontal direction.

When the piezoelectric actuator 130 is configured as described above, the positive electrode 131 may include the positive electrode dummy pattern 136 and the negative electrode layer 133 may include the negative dummy pattern 137. Thus, the electrode layers provided on the uppermost surface or the lowermost surface of the piezoelectric actuator 130 may include the dummy patterns 136 and 137. Of course, in this case, the positive electrode connection pillar 134 and the negative electrode connection pillar 135 may connect all the layers from the uppermost layer to the lowermost layer of the piezoelectric actuator 130.

In the piezoelectric actuator 130 having such a structure according to the present embodiment, upper and lower surfaces thereof in the vertical direction may not be discriminated. Namely, in the case of the piezoelectric actuator 130 according to the present embodiment, since the positive electrode and the negative electrode are simultaneously exposed to the upper and lower surfaces in the vertical direction, an external electrode may be disposed on any one of the upper surface and the lower surface thereof in the vertical direction, so it can be easily connected to an external power source. In other words, an external electrode provided on any of the upper and lower surfaces of the piezoelectric actuator 130 in the vertical direction may be connected to an electrode connection portion of the board to drive the piezoelectric actuator 130. In this case, the external electrode may be provided in a position corresponding to less than 50% of maximum displacement when the piezoelectric actuator 130 is driven. Of course, the piezoelectric actuator 130 may also be connected to the electrode connection portion of the board without any external electrode.

Hereinafter, a piezoelectric actuator 130′ according to another embodiment of the present invention will be described.

The piezoelectric actuator 130′ according to another embodiment of the present invention may be discriminated from the piezoelectric actuator 130 according to the former embodiment, in that the lowermost layer of the electrode layers does not have a dummy pattern. Namely, the vertical upper surface and the lower surface of the piezoelectric actuator 130′ according to another embodiment of the present invention are discriminated.

Hereinafter, on the portions different from those of the piezoelectric actuator 130 according to the former embodiment of the present invention will be described and a description of the same portions will be replaced by the description with respect to the piezoelectric actuator 130 according to the former embodiment of the present invention.

Meanwhile, in FIG. 7, it is illustrated that the positive electrode connection pillar 134 and the negative electrode connection pillar 135 connect both the uppermost layer and the lowermost layer in the exploded perspective view, but this is only for the purpose of illustrating the interlayer connection structure and actual lengths of the positive electrode connection pillar 134 and the negative electrode connection pillar 135 are not substantially the same as those illustrated. The actual lengths of the positive electrode connection pillar 134 and the negative electrode connection pillar 135 may be equal to a thickness in a state that all the layers including the uppermost layer and the lowermost layer are attached, i.e., vertical lengths.

The lowermost layer of the piezoelectric actuator 130′ according to another embodiment of the present invention may not have a dummy pattern. The lowermost layer may be a positive electrode layer 131 or a negative electrode layer 133.

In the case that the lowermost layer is provided as the positive electrode layer 131, only the positive electrode connection pillar 134 may be connected from the uppermost layer to the lowermost layer. The negative electrode connection pillar 135 may not be connected to the positive electrode layer 131 provided as the lowermost layer but connected only to the negative electrode layer 133 provided thereabove with the piezoelectric element layer 132 interposed therebetween.

In the case that the lowermost layer is provided as a negative electrode layer 133, only the negative electrode connection pillar 135 may be connected from the uppermost layer to the lowermost layer. The positive electrode connection pillar 134 may not be connected to the negative electrode layer 133 provided as the lowermost layer but connected only to the positive electrode layer 131 provided thereabove with the piezoelectric element layer 132 interposed therebetween.

In the piezoelectric actuator 130′ having such a structure according to the present embodiment, upper and lower surfaces thereof in the vertical direction may be discriminated from one another. Namely, in the case of the piezoelectric actuator 130′ according to another embodiment of the present invention, since the positive electrode and the negative electrode are simultaneously exposed to the upper surface thereof in a vertical direction, an external electrode may be provided on the upper surface in the vertical direction, so it can be easily connected to an external power source. However, only any one of a positive electrode and a negative electrode may be exposed to the lower surface thereof in the vertical direction. In this case, the external electrode provided on the upper surface in the vertical direction may be connected to the electrode connection portion of the board to drive the piezoelectric actuator 130′. Of course, power may be supplied to an external electrode connected to any one electrode exposed to the lower surface in the vertical direction and power may be supplied to an external electrode provided on the upper surface in the vertical direction and connected to an electrode different from the electrode exposed to the lower surface in the vertical direction to drive the piezoelectric actuator 130′. Of course, the piezoelectric actuator 130 may also be connected to the electrode connection portion of the board without an external electrode.

As set forth above, according to embodiments of the invention, the electrodes laminated vertically in the piezoelectric actuator can be easily connected to one another.

In addition, since the electrodes laminated vertically in the piezoelectric actuator are connected in the central portion of the piezoelectric actuator which is not greatly changed, performance of the piezoelectric actuator can be enhanced and a lifespan of the piezoelectric actuator can be lengthened.

While the present invention has been shown and described in connection with the embodiments, it will be apparent to those skilled in the art that modifications and variations can be made without departing from the spirit and scope of the invention as defined by the appended claims.

What is claimed is:

1. An apparatus for generating vibrations, the apparatus comprising:
a housing having an internal space;
a direction changing member installed in the housing so as to be disposed in the internal space;
a piezoelectric actuator fixed to the direction changing member such that a horizontal deformation thereof is restrained, and deforming the direction changing member by a horizontal deformation thereof; and
a vibrator fixed to the direction changing member and vertically displaced in a vertical direction according to a vertical deformation of the piezoelectric actuator,
wherein the piezoelectric actuator comprises
positive electrode layers and negative electrode layers iteratively alternately vertically laminated,
piezoelectric element layers interposed between the positive electrode layers and the negative electrode layers, respectively,
a positive electrode connection pillar provided in a position corresponding to less than 50% of maximum displacement in the event of driving and penetrating the electrode layers and the piezoelectric element layers to connect the positive electrode layers, and
a negative electrode connection pillar provided in a position corresponding to less than 50% of maximum displacement in the event of driving and penetrating the electrode layers and the piezoelectric element layers to connect the negative electrode layers.

2. The apparatus of claim 1, wherein the direction changing member comprises:
a fixed end fixed to the housing;
horizontal portions extending from the fixed end to both sides in a horizontal direction;
vertical portions extending from horizontal outer portions of the horizontal portions downwardly in a vertical direction; and
displacement extending portions extending from vertical lower portions of the vertical portions to both sides in a horizontal direction and having the vibrator fixed to both sides thereof in the horizontal direction.

3. The apparatus of claim 2, wherein the piezoelectric actuator is provided in a space formed by the horizontal portions and the vertical portions.

4. The apparatus of claim 2, wherein the piezoelectric actuator is attached to one surface of at least any one of an upper surface in a vertical direction and end and side surfaces in a horizontal direction.

5. The apparatus of claim 1, wherein the housing comprises a bracket on which the direction changing member is installed, and a case covering the bracket and incorporated with the bracket to provide an internal space.

6. The apparatus of claim 1, further comprising a board attached to the bracket and providing power to the piezoelectric actuator.

7. The apparatus of claim 1, wherein the positive electrode layers have a quadrangular shape having a horizontal side and a vertical side, and the positive electrode connection pillar and the negative electrode connection pillar are provided in a position corresponding to less than 50% of maximum displacement in the event of driving in a horizontal direction.

8. The apparatus of claim 7, wherein the positive electrode layer has a positive dummy pattern formed on one side of a portion corresponding to less than 50% of maximum displacement in a vertical direction in the event of driving in a horizontal direction, and separated from the positive electrode layer,
the negative electrode layer has a negative dummy pattern formed in the other side of the portion corresponding to less than 50% of maximum displacement in a vertical direction in the event of driving in the horizontal direction, and separated from the negative electrode layer,
the positive electrode is connected in a penetrative manner vertically in the other side in a vertical direction where the negative dummy pattern is provided, and
the negative electrode connection pillar is connected in a penetrative manner vertically on one side in the vertical direction where the positive electrode dummy pattern is provided.

9. The apparatus of claim 8, wherein the positive electrode dummy pattern and the negative electrode dummy pattern are provided symmetrically, based on the center of the piezoelectric actuator in the vertical direction and have the same shape.

10. The apparatus of claim 7, wherein the vertical side is shorter than the horizontal side.

11. The apparatus of claim 8, wherein the lowermost layer of the electrode layers does not have a dummy pattern.

12. The apparatus of claim 11, wherein only a connection pillar having a corresponding polarity is connected to the lowermost layer of the electrode layers.
